(19) United States
(12) Patent Application Publication
(10) Pub. No.: US 2026/0318758 A1
(43) Pub. Date: Oct. 15, 2026

(54) PRESSURE SENSOR, PRESSURE POINT DETECTION METHOD, AND PRESSURE POINT DETECTION PROGRAM

(71) Applicant: Murata Manufacturing Co., Ltd., Nagaokakyo-shi (JP)

(72) Inventor: Yuuki TACHIBANA, Nagaokakyo-shi (JP)

(21) Appl. No.: 19/699,091

(22) Filed: Jun. 5, 2026

Related U.S. Application Data
(63) Continuation of application No. PCT/JP2024/042618, filed on Dec. 3, 2024.

(30) Foreign Application Priority Data
Dec. 26, 2023 (JP) 2023-218798

(51) Int. Cl. G01L 1/16; G01L 1/04

(52) U.S. Cl. CPC G01L 1/16; G01L 1/04

(57) ABSTRACT

A pressure sensor includes a piezoelectric film; detection electrodes on a first principal surface of the piezoelectric film that detect charges generated in the piezoelectric film; a ground electrode on a second principal surface of the piezoelectric film; a detection unit that detects a voltage signal generated in the piezoelectric film from a detected charge; and a processor that processes the voltage signal. The processor is configured to define first second directions perpendicular to each other on the first principal surface, determine a distribution of polarization on the first principal surface; obtain a first line segment extending in the first direction and a second line segment extending in the second direction that form a boundary at which the polarization discontinuously changes among a positive value, a negative value, and a value of 0; and detect a pressure point based on an intersection of the first and second line segments.

### CROSS REFERENCE TO RELATED APPLICATIONS

This application is a continuation of International Application No. PCT/JP 2024/042618, filed Dec. 3, 2024, which claims priority to Japanese Patent Application No. 2023-218798, filed Dec. 26, 2023, the contents of each of which are hereby incorporated by reference in their entireties.

### TECHNICAL FIELD

The present disclosure relates to a technique for detecting pressure.

### BACKGROUND

Conventionally, in a product on which a general pressure-sensitive track pad is mounted, a displacement amount of a housing due to a pressing operation by a user is measured using a strain sensor, an ultrasonic sensor, or a capacitive touch panel (for example, as described in Japanese Patent Application Laid-Open No. 2017-78888), so that pressure applied to an operation surface is estimated to detect the pressing operation by the user.

As described above, a general pressure-sensitive track pad measures a displacement amount of the housing due to pressing. Therefore, in order to mount the pressure-sensitive track pad on a product, it is necessary to consider a housing structure that equalizes the displacement amount of the housing and an arrangement of a sensor element that measures the displacement amount of the housing. Therefore, the cost of the housing design is high, and the restriction of the housing design is also large.

Further, since there are significant restrictions on the housing design, it is necessary to design each product individually. Therefore, restrictions on product cost and product design increase.

### SUMMARY OF THE INVENTION

In view of the foregoing, an exemplary aspect the present disclosure provides a technique for reducing restrictions on housing design when a pressure sensor is mounted on a product.

In an exemplary aspect, a pressure sensor is provided that includes a piezoelectric film including a first principal surface and a second principal surface opposite to the first principal surface; a plurality of detection electrodes on the first principal surface of the piezoelectric film and configured to detect charges generated in the piezoelectric film; a ground electrode on the second principal surface of the piezoelectric film; a detection unit configured to detect a voltage signal generated in the piezoelectric film from a charge detected by the detection electrode; and a processor configured to define a first direction and a second direction perpendicular to the first direction on the first principal surface of the piezoelectric film, determine a distribution of polarization on the first principal surface of the piezoelectric film based on the detected voltage signal; obtain a first line segment extending in the first direction that forms a boundary at which the polarization discontinuously changes among a positive value, a negative value, and a value of 0; obtain a second line segment extending in the second direction that forms a boundary at which the polarization discontinuously changes among a positive value, a negative value, and a value of 0; and detect a pressure point by obtaining an intersection of the first line segment and the second line segment.

In another aspect, a pressure point detection method is provided for a pressure sensor that includes a piezoelectric film including a first principal surface and a second principal surface opposite to the first principal surface; a plurality of detection electrodes on the first principal surface of the piezoelectric film and configured to detect charges generated in the piezoelectric film; a ground electrode on the second principal surface of the piezoelectric film; a detection unit configured to detect a voltage signal generated in the piezoelectric film from a charge detected by the detection electrode; and a processor. The method includes defining a first direction and a second direction perpendicular to the first direction on the first principal surface of the piezoelectric film, determining a distribution of polarization on the first principal surface of the piezoelectric film based on a voltage signal; obtaining a first line segment extending in the first direction that forms a boundary at which the polarization discontinuously changes among a positive value, a negative value, and a value of 0; obtaining a second line segment extending in the second direction that forms a boundary at which the polarization discontinuously changes among a positive value, a negative value, and a value of 0; and detecting a pressure point by obtaining an intersection of the first line segment and the second line segment.

In yet another exemplary aspect, a pressure point detection program is provided that is installed in a pressure sensor that includes a piezoelectric film including a first principal surface and a second principal surface opposite to the first principal surface; a plurality of detection electrodes on the first principal surface of the piezoelectric film and configured to detect charges generated in the piezoelectric film; a ground electrode on the second principal surface of the piezoelectric film; a detection unit configured to detect a voltage signal generated in the piezoelectric film from a charge detected by the detection electrode; and a processor that processes the voltage signal detected by the detection unit. In this aspect, the program causes the processor to define a first direction and a second direction perpendicular to the first direction on the first principal surface of the piezoelectric film, determine a distribution of polarization on the first principal surface of the piezoelectric film based on a voltage signal; obtain a first line segment extending in the first direction that forms a boundary at which the polarization discontinuously changes among a positive value, a negative value, and a value of 0; obtain a second line segment extending in the second direction that forms a boundary at which the polarization discontinuously changes among a positive value, a negative value, and a value of 0; and detect a pressure point by obtaining an intersection of the first line segment and the second line segment.

According to the exemplary aspects of the present disclosure, restrictions on housing design can be reduced when a pressure sensor is mounted on a product.

### BRIEF DESCRIPTION OF DRAWINGS

FIG. 1 is a functional block diagram of a pressure sensor 1.

FIG. 2 is an external perspective view of a piezoelectric sensor 11.

FIG. 3 is a sectional view of the piezoelectric sensor 11.

FIG. 4 is a sectional view of a piezoelectric film sensor 15.

FIG. 5(A) is a conceptual diagram illustrating an example of deformation of a principal surface 31 of the piezoelectric film sensor against pressure. FIG. 5(B) is a conceptual diagram illustrating polarization of the piezoelectric film when the principal surface 31 of the piezoelectric film sensor is deformed as illustrated in FIG. 5(A).

FIG. 6(A) is a conceptual diagram illustrating another example of deformation of the principal surface 31 of the piezoelectric film sensor against pressure. FIG. 6(B) is a conceptual diagram illustrating polarization of the piezoelectric film when the principal surface 31 of the piezoelectric film sensor is deformed as illustrated in FIG. 6(A).

FIG. 7 is a flowchart illustrating pressure detection processing by a processor.

FIG. 8 is a conceptual diagram for explaining pressure detection processing by the processor.

FIG. 9(A) is a conceptual diagram illustrating an example of deformation of the principal surface 31 of the piezoelectric film sensor against pressure. FIG. 9(B) is a conceptual diagram illustrating polarization of the piezoelectric film when the principal surface 31 of the piezoelectric film sensor is deformed as illustrated in FIG. 9(A).

FIG. 10 is a flowchart illustrating pressure detection processing by the processor according to a first modification.

FIG. 11 is a conceptual diagram for explaining pressure detection processing by the processor according to the first modification.

FIG. 12(A) is a conceptual diagram illustrating an example of deformation of the principal surface 31 of the piezoelectric film sensor against pressure. FIG. 12(B) is a conceptual diagram illustrating polarization of the piezoelectric film when the principal surface 31 of the piezoelectric film sensor is deformed as illustrated in FIG. 12(A).

FIG. 13(A) is a conceptual diagram illustrating another example of deformation of the principal surface 31 of the piezoelectric film sensor against pressure. FIG. 13(B) is a conceptual diagram illustrating an example of polarization of the piezoelectric film when the principal surface 31 of the piezoelectric film sensor is deformed as illustrated in FIG. 13(A).

FIG. 14 is a flowchart illustrating pressure detection processing by the processor according to a second modification.

FIG. 15 is a flowchart illustrating processing of step s33 by the processor according to the second modification.

FIG. 16 is a conceptual diagram for explaining pressure detection processing by the processor according to the second modification.

FIG. 17 is a conceptual diagram for explaining pressure detection processing by the processor according to the second modification.

FIG. 18 is a sectional view of a piezoelectric sensor 11a.

FIG. 19 is a sectional view of a piezoelectric sensor 11b.

### DETAILED DESCRIPTION

Hereinafter, a plurality of exemplary embodiments of the present disclosure will be described. In each embodiment, a difference from description before the embodiment will be mainly described. The same function and effect by the same configuration will not be mentioned for each embodiment.

### Exemplary Embodiment

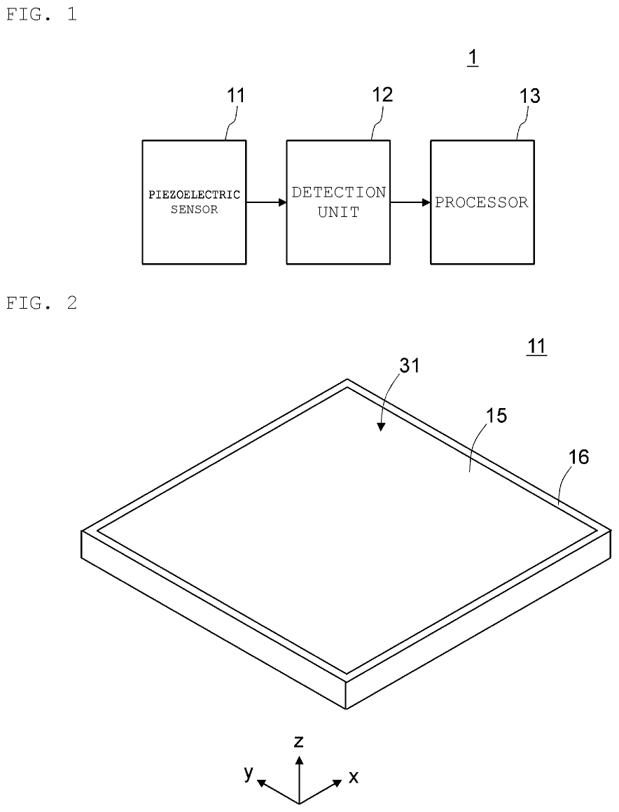

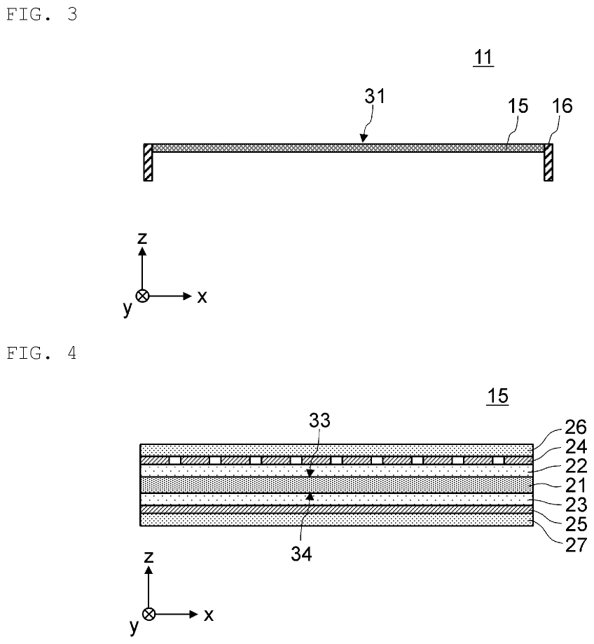

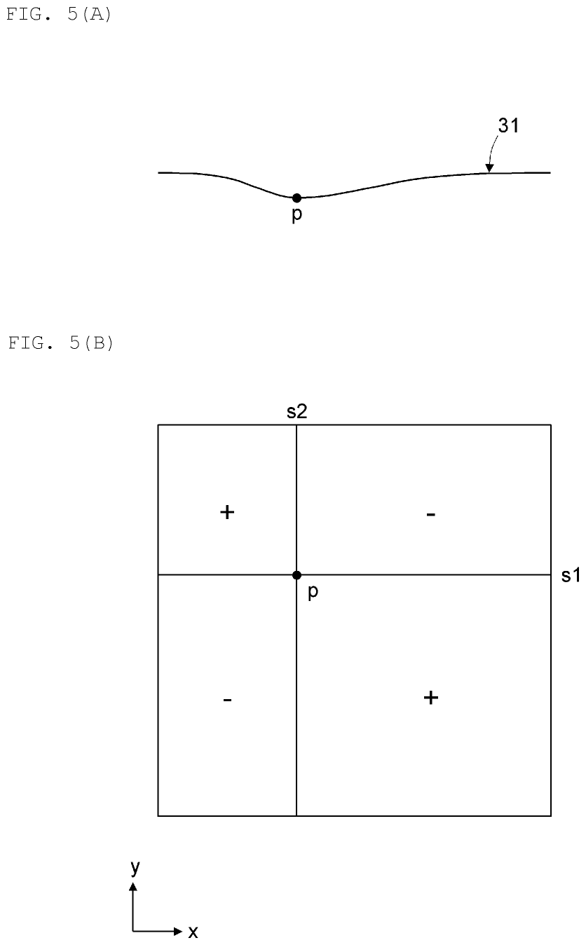

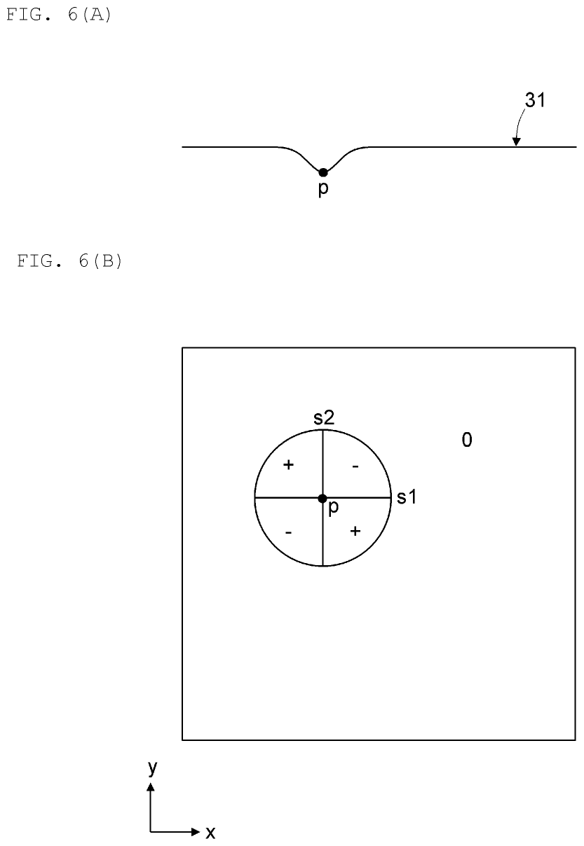

FIG. 1 is a functional block diagram of the pressure sensor 1. FIG. 2 is an external perspective view of the piezoelectric sensor 11. FIG. 3 is a sectional view of the piezoelectric sensor 11. FIG. 4 is a sectional view of the piezoelectric film sensor 15. The pressure sensor 1 includes the piezoelectric sensor 11, a detection unit 12, and a processor 13. The piezoelectric sensor 11 includes the piezoelectric film sensor 15 and a supporting member 16. The piezoelectric film sensor 15 includes a piezoelectric film 21, adhesives 22, 23, a plurality of detection electrodes 24, a ground electrode 25, and flexible substrates 26, 27.

As illustrated in FIGS. 2 and 3, the piezoelectric film sensor 15 is supported by the supporting member 16 in a state of being stretched in all directions parallel to the principal surface 31 of the piezoelectric film sensor 15.

The pressure sensor 1 is configured to detect pressure applied to the principal surface 31 of the piezoelectric film sensor 15 at one point.

As illustrated in FIG. 4, the piezoelectric film 21 has a first principal surface 33 and a second principal surface 34 opposite to the first principal surface 33 and has output anisotropy. In an exemplary aspect, the piezoelectric film 21 is formed of, for example, uniaxially stretched poly-L-lactic acid (PLLA). The detection electrode 24 is arranged on the first principal surface 33 of the piezoelectric film 21 and is configured to detect a charge generated in the piezoelectric film 21. The detection electrode 24 is formed on a flexible substrate 26 and is attached to the first principal surface 33 of the piezoelectric film 21 by the adhesive 22. The ground electrode 25 is arranged on the second principal surface 34 of the piezoelectric film 21. The ground electrode 25 is formed on the flexible substrate 27 and is attached to the second principal surface 34 of the piezoelectric film 21 by the adhesive 23.

The detection unit 12 is configured to detect a voltage signal generated in the piezoelectric film 21 from the charge detected by the detection electrode 24. The detection unit 12 includes, for example, a charge amplifier circuit, an amplifier circuit, and an A/D conversion circuit. The processor 13 is configured to process the voltage signal detected by the detection unit 12. In an exemplary aspect, the processor 13 includes a CPU, a memory (e.g., a non-transitory computer-readable storage medium), and the like, stores a program (e.g., software instructions) that is executable by the processor 13, and processes a voltage signal by executing the program.

In the present specification and for purposes of this disclosure, a predetermined direction parallel to the first principal surface 33 of the piezoelectric film 21 according to the distribution of polarization on the first principal surface 33 of the piezoelectric film 21 is defined as an x-axis direction. A direction parallel to the first principal surface 33 of the piezoelectric film 21 and perpendicular to the x-axis direction is defined as a y-axis direction. A direction perpendicular to the first principal surface 33 of the piezoelectric film 21 is defined as a z-axis direction. One side in the x-axis direction is defined as a right direction or a +x-axis direction, and the other side in the x-axis direction is defined as a left direction or the −x-axis direction. One side in the y-axis direction is defined as an upward direction or a +y-axis direction, and the other side in the y-axis direction is defined as a downward direction or a −y-axis direction.

The processor 13 is configured to set an x-axis direction (e.g., a first direction) and a y-axis direction (e.g., second direction) perpendicular to the x-axis direction on the first principal surface 33 of the piezoelectric film 21. As a result, the processor 13 is configured to determine the orientation of the coordinate system on the first principal surface 33 of the piezoelectric film 21. The processor 13 is configured to determine a distribution of polarization on the first principal surface 33 of the piezoelectric film 21 based on the voltage signal. As will be described in detail below, the processor 13 is configured to obtain a first line segment extending in the x-axis direction that forms a boundary where polarization discontinuously changes among a positive value, a negative value, and a value of 0. In other words, the first line segment is a line segment in which the polarity of polarization changes with the first line segment as a boundary. The processor 13 is also configured to obtain a second line segment extending in the y-axis direction that forms a boundary at which the polarization discontinuously changes among a positive value, a negative value, and a value of 0. In other words, the second line segment is a line segment in which the polarity of polarization changes with the second line segment as a boundary. Then, the processor 13 is configured to detect the pressure points by obtaining an intersection of the first line segment and the second line segment.

As illustrated in FIG. 4, the detection electrodes 24 are arranged in the x-axis direction and the y-axis direction on the piezoelectric film 21. The processor 13 is configured to define cells arranged in the x-axis direction and the y-axis direction on the first principal surface 33 of the piezoelectric film 21. The cell corresponds to a region occupied by one detection electrode 24 on the first principal surface 33 of the piezoelectric film 21 in a plan view of the first principal surface 33 of the piezoelectric film 21. The processor 13 is configured to determine the polarization of the piezoelectric film 21 for the cell corresponding to each detection electrode 24 based on the voltage signal corresponding to each detection electrode 24.

In a modification, the processor 13 may determine the distribution of the polarization by estimating the polarization with respect to positions arranged at narrower intervals or continuous positions.

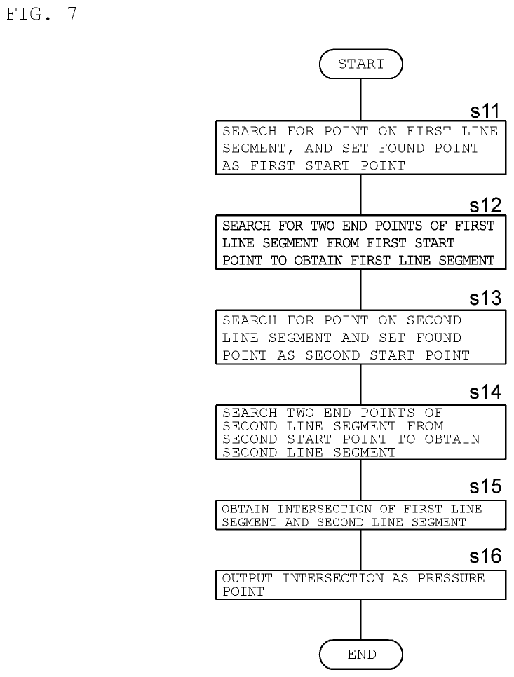

FIG. 5(A) is a conceptual diagram illustrating an example of deformation of the principal surface 31 of the piezoelectric film sensor against pressure. FIG. 5(B) is a conceptual diagram illustrating polarization of the piezoelectric film when the principal surface 31 of the piezoelectric film sensor is deformed as illustrated in FIG. 5 (A). FIG. 6(A) is a conceptual diagram illustrating another example of deformation of the principal surface 31 of the piezoelectric film sensor against pressure. FIG. 6(B) is a conceptual diagram illustrating polarization of the piezoelectric film when the principal surface 31 of the piezoelectric film sensor is deformed as illustrated in FIG. 6(A).

In FIG. 5(A), the piezoelectric film sensor, that is, the piezoelectric film is deformed not only at a pressure point p but also entirely by pressing. As illustrated in FIG. 5(B), the polarization of the piezoelectric film changes over the entire first principal surface of the piezoelectric film according to the deformation. In FIG. 6(A), the piezoelectric film sensor, that is, the piezoelectric film is locally deformed around the pressure point p by pressing. As illustrated in FIG. 6(B), the polarization of the piezoelectric film locally changes around the pressure point p according to the deformation, and becomes a value of 0 at a position away from the pressure point p.

As illustrated in FIG. 5(B) and 6(B), the polarization of the upper left region of the pressure point p and the polarization of the lower right region of the pressure point p exhibit polarization of the same positive or negative sign. The polarization of the lower left region of the pressure point p and the polarization of the upper right region of the pressure point p exhibit polarization of the same positive or negative sign. The polarization of the upper left region of the pressure point p and the polarization of the lower left region of the pressure point p exhibit polarization of the opposite positive or negative sign. In FIG. 5(B) and 6(B), the polarization of the upper left and lower right regions of the pressure point p is a positive value, and the polarization of the lower left and upper right regions of the pressure point p is a negative value.

Such a distribution of polarization appears because the piezoelectric film has output anisotropy.

In the diagrams illustrating the distribution of polarization as illustrated in FIG. 5(B) and 6(B), for convenience of explanation, the distribution of polarization is drawn by approximately regarding the distribution of polarization for detected discrete points as the distribution of polarization for continuous points. For this reason, boundary lines s1, s2 where the positive and negative signs of polarization change correspond to boundary lines of adjacent cells or a row of cells where the polarization takes a value of 0.

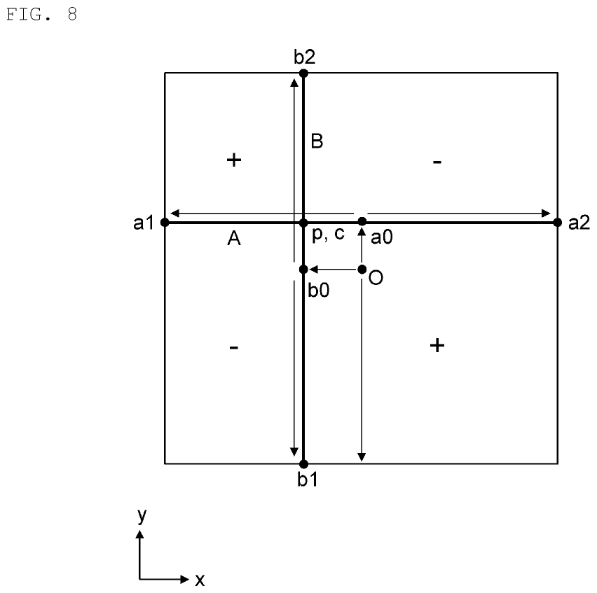

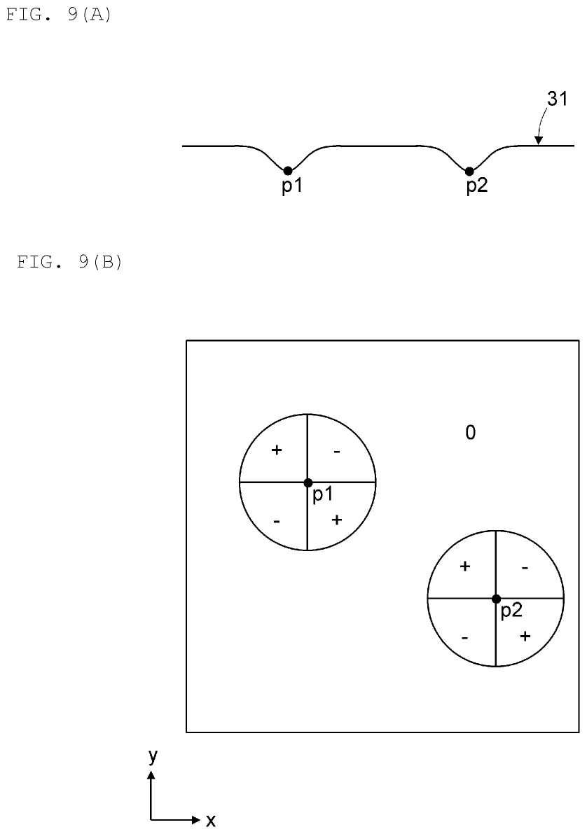

FIG. 7 is a flowchart illustrating pressure detection processing by the processor. FIG. 8 is a conceptual diagram for explaining pressure detection processing by the processor.

As illustrated in FIG. 7, first, the processor searches for a point on the first line segment that forms a boundary where polarization discontinuously changes among a positive value, a negative value, and a value of 0 on the first principal surface of the piezoelectric film and extends in the x-axis direction, and sets the found point as a first start point (s11). When a point on the first principal surface of the piezoelectric film satisfies the following condition, the point corresponds to a point on the first line segment. That is, in the y-axis direction, the polarization changes from a positive value to a negative value, from a negative value to a positive value, from a positive value to a 0 value, from a 0 value to a positive value, from a negative value to a 0 value, or from a 0 value to a negative value, with a point in the vicinity of the point in the x-axis direction as a boundary. In the y-axis direction, the polarization changes discontinuously, that is, abruptly, for example, more than a predetermined threshold, with a point in the vicinity of the point in the x-axis direction as a boundary.

For example, when a position (i, j) satisfies sgn[P(i+k, j+1)]≠sgn[P(i+k, j−1)], |P(i+k, j+1)−P(i+k, j−1)|>α for k=0, 1, k=0, −1, or k=1, −1, the processor determines that the position (i, j) corresponds to a point on the first line segment. In the expression (i, j), i represents the position of the cell in the x-axis direction, and j represents the position of the cell in the y-axis direction. It is noted that the term “P(i, j)” represents polarization at position (i, j). Moreover, the term “α” represents a predetermined threshold that defines the discontinuity of polarization changes. The term “sgn[x]” is a sign function, and returns 1 when x>0, returns 0 when x=0, and returns −1 when x<0.

In the method of determining whether a point on the first principal surface of the piezoelectric film is a point on the first line segment, the first line segment is adjusted to be a line segment extending in the x-axis direction through the pressure point.

For example, the processor can be configured to set an origin of a coordinate system at the center of gravity (e.g., a geometric center of gravity) of the first principal surface of the piezoelectric film, examine or scan points on the first principal surface of the piezoelectric film from the origin toward the lower end and the upper end, and repeat searching for a point on the first line segment from the origin to the left end and toward the right end. Alternatively, the processor may repeat, from the left end to the right end, searching for a point on the first line segment by examining a point on the first principal surface of the piezoelectric film from the lower end to the upper end. The processor may be configured to search for a point on the first line segment by examining points on the first principal surface of the piezoelectric film in another order.

In FIG. 8, the processor searches for a point on the first line segment, examines a point on the first principal surface of the piezoelectric film from an origin O toward the lower end and the upper end, finds a first start point a0, and ends the search for a point on the first line segment.

Next, the processor searches for two end points of the first line segment by examining points on the first principal surface of the piezoelectric film in the left direction and the right direction from the first start point and finds the two end points to obtain the first line segment (s12).

For example, when the position (i, j) is a point on the first line segment and is at the right end or the left end of the first principal surface of the piezoelectric film, the processor can be configured to determine that the position (i, j) is an end point of the first line segment. In addition, when the position (i, j) is a point on the first line segment and a next position (i+1, j) or a position (i−1, j) is not a point on the first line segment, the processor can be configured to determine that the position (i, j) is an end point of the first line segment.

In FIG. 8, the processor searches for two end points of the first line segment by examining points on the first principal surface of the piezoelectric film from the first start point a0 in the left direction and the right direction, and finds two end points a1, a2 of the first line segment, thereby obtaining the first line segment A.

Next, on the first principal surface of the piezoelectric film, the processor searches for a point on the second line segment that forms a boundary where polarization discontinuously changes among a positive value, a negative value, and a value of 0 and extends in the y-axis direction, and sets the found point as a second start point (s13). When a point on the first principal surface of the piezoelectric film satisfies the following condition, the point corresponds to a point on the second line segment. That is, in the x-axis direction, the polarization changes from a positive value to a negative value, from a negative value to a positive value, from a positive value to a 0 value, from a 0 value to a positive value, from a negative value to a 0 value, or from a 0 value to a negative value, with a point in the vicinity of the point in the y-axis direction as a boundary. In the x-axis direction, the polarization changes discontinuously, that is, abruptly, for example, more than a predetermined threshold, with a point in the vicinity of the point in the y-axis direction as a boundary.

For example, when the position (i, j) satisfies sgn[P(i+1, j+k)]≠sgn[P(i−1, j+k)], |P(i+1, j+k)−P(i−1, j+k)|>α for k=0, 1, k=0, −1, or k=1, −1, the processor is configured to determine that the position (i, j) corresponds to a point on the second line segment.

In the method of determining whether a point on the first principal surface of the piezoelectric film is a point on the second line segment, the second line segment is adjusted to be a line segment extending in the y-axis direction through the pressure point.

For example, the processor can be configured to repeat examining a point on the first principal surface of the piezoelectric film from the origin toward the left end and the right end to search for a point on the second line segment from the origin toward the lower end and the upper end. Alternatively, the processor can be configured to repeat, from the lower end to the upper end, searching for a point on the second line segment by examining a point on the first principal surface of the piezoelectric film from the left end to the right end. The processor can be configured to search for a point on the second line segment by examining points on the first principal surface of the piezoelectric film in another order.

In FIG. 8, the processor searches for a point on the second line segment, examines a point on the first principal surface of the piezoelectric film from the origin O toward the left end, finds a second start point b0, and ends the search for a point on the second line segment.

Next, the processor searches for two end points of the second line segment by examining points on the first principal surface of the piezoelectric film downward and upward from the second start point and finds the two end points to obtain the second line segment (s14).

For example, when the position (i, j) is a point on the second line segment and is at the upper end or the lower end of the first principal surface of the piezoelectric film, the processor can be configured to determine that the position (i, j) is the end point of the second line segment. In addition, when the position (i, j) is a point on the second line segment and the next position (i, j+1) or the position (i, j−1) is not a point on the second line segment, the processor can be configured to determine that the position (i, j) is an end point of the second line segment.

In FIG. 8, the processor searches for two end points of the second line segment by examining points on the first principal surface of the piezoelectric film downward and upward from the second start point b0, and finds two end points b1 and b2 of the second line segment to obtain the second line segment B.

Next, the processor obtains an intersection of the first line segment and the second line segment (s15), and outputs the intersection as a pressure point (s16). The first line segment and the second line segment are line segments extending in the x-axis direction and the y-axis direction through the pressure point, respectively. Therefore, an intersection of the first line segment and the second line segment coincides with the pressure point.

In FIG. 8, the processor obtains an intersection c between the first line segment A and the second line segment B, and outputs the intersection c as a pressure point. As illustrated in FIG. 8, the intersection c coincides with the pressure point p.

The processor repeats steps s11 to s16 every certain period. In this manner, the pressure sensor 1 detects the pressure point.

In the modification, the processor may obtain the first line segment and the second line segment by another method. For example, the processor may obtain the first line segment and the second line segment using various edge or line detection methods proposed in the field of image processing.

In another modification, the processor may execute steps s11 and s12 after executing steps s13 and s14.

Note that the first line segment and the second line segment include cells of one column or a plurality of columns according to a method of detecting the first line segment and the second line segment. Therefore, the intersection between the first line segment and the second line segment includes a single cell or a plurality of cells according to the method of detecting the first line segment and the second line segment.

It is noted that, when the first start point, the second start point, or the intersection between the first line segment and the second line segment cannot be found, the processor determines that there is no pressure point and outputs nothing in an exemplary aspect.

According to the present embodiment, the restriction of the housing design when mounting the pressure sensor on a product is only that the principal surface of the piezoelectric film sensor is most recessed at the pressure point. Therefore, the restriction of the housing design when mounting the pressure sensor on the product is reduced. In addition, the degree of freedom of product design is thus improved.

In addition, since a general pressure-sensitive track pad measures a displacement amount of a housing in principle, it is affected by gravity due to a posture of the housing, and when elasticity of the housing decreases due to aging deterioration or the like, there is a possibility that pressing is erroneously detected even though a user does not apply pressure. According to the present embodiment, the pressure sensor detects pressure by capturing a characteristic of distribution of polarization on the first principal surface of the piezoelectric film. The distribution of the polarization generated by the pressure has a characteristic different from the distribution of the polarization generated by the above-described factors. For this reason, the influence of gravity applied to the piezoelectric film sensor on pressure detection by the pressure sensor is reduced. In addition, the possibility that the pressure sensor erroneously detects the pressure is reduced.

Further, the piezoelectric sensor has a simple structure including a piezoelectric film sensor and a supporting member. The processor is configured to detect pressure at one point by obtaining an intersection of the first line segment and the second line segment. Therefore, in the present embodiment, the pressure at a single point can be detected by a simple structure.

### First Modification

A pressure sensor of a first modification is different from the pressure sensor 1 in the following points. That is, the processor obtains all of the first line segment and the second line segment and obtains all of intersections between the first line segment and the second line segment.

The pressure sensor of the first modification is configured to detect pressure at one point or a plurality of points.

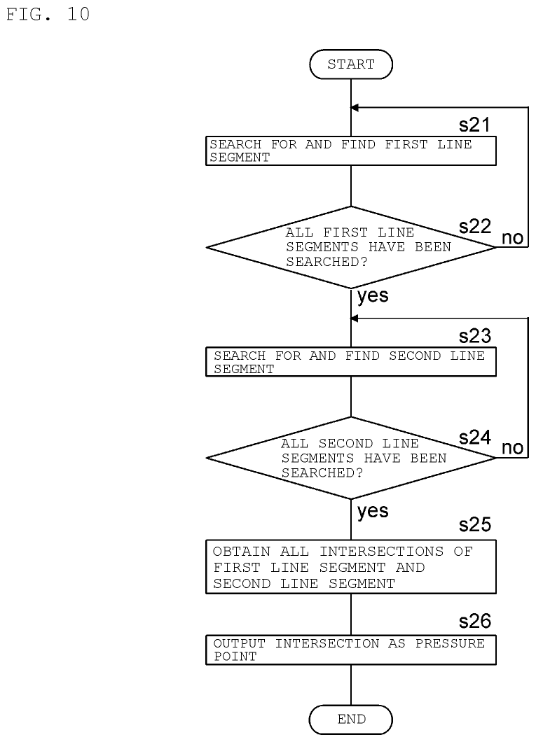

FIG. 9(A) is a conceptual diagram illustrating an example of deformation of the principal surface 31 of the piezoelectric film sensor against pressure. FIG. 9(B) is a conceptual diagram illustrating polarization of the piezoelectric film when the principal surface 31 of the piezoelectric film sensor is deformed as illustrated in FIG. 9(A).

FIG. 9(A) illustrates a state in which deformation of the principal surface 31 of the piezoelectric film sensor is viewed along a direction from a pressure point p1 toward a pressure point p2.

In FIG. 9(A), the piezoelectric film sensor, that is, the piezoelectric film is locally deformed around the two pressure points p1 and p2. As illustrated in FIG. 9(B), the polarization of the piezoelectric film locally changes around the pressure points p1 and p2 according to the deformation and takes a value of 0 at a position away from the pressure points p1 and p2.

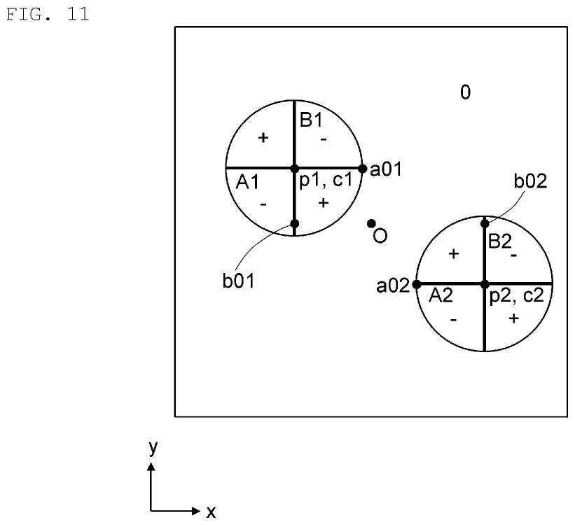

FIG. 10 is a flowchart illustrating pressure detection processing by the processor according to the first modification. FIG. 11 is a conceptual diagram for explaining the pressure detection processing by the processor according to the first modification.

As illustrated in FIG. 10, first, the processor performs processing similar to steps s11 and s12 illustrated in FIG. 7 to search for and find the first line segment (s21). When the search for all the first line segments has not been completed (s22: no), the search for the first line segment is resumed.

More specifically, the processor starts searching for a point on the first line segment from a predetermined point such as an origin. Next, the first line segment is obtained from the found point on the first line segment. However, when the found point on the first line segment is on the already found first line segment, it is not necessary to obtain the first line segment from the point on the first line segment. Next, the search for the point on the first line segment is resumed from the point next to the point examined most recently for the point on the first line segment. When all the points on the first principal surface of the piezoelectric film have been examined, the processor ends the search for the points on the first line segment.

In FIG. 11, the processor starts searching for a point on the first line segment from the origin O, finds a first start point a01, and obtains a first line segment A1. Then, the search for the point on the first line segment is resumed from the point next to the first start point a01, whereby a first start point a02 is found and a first line segment A2 is obtained.

When all the first line segments have been searched (s22: yes), the processor searches and finds the second line segment by executing processing similar to steps s13 and s14 illustrated in FIG. 7 (s23). When the search for all the second line segments has not been completed (s24: no), the search for the second line segments is resumed.

More specifically, after completing the search for the point on the first line segment, the processor starts the search for the point on the second line segment from a predetermined point such as the origin. Next, the second line segment is obtained from the found point on the second line segment. However, when the found point on the second line segment is on the already found second line segment, it is not necessary to obtain the second line segment from the point on the second line segment. Next, the search for the point on the second line segment is resumed from the point next to the point examined most recently for the point on the second line segment. When all the points on the first principal surface of the piezoelectric film have been examined, the processor ends the search for the points on the second line segment.

In FIG. 11, the processor starts searching for a point on the second line segment from the origin O, finds a second start point b01, and obtains a second line segment B1. Then, the search for the point on the second line segment is resumed from the point next to the second start point b01, a second start point b02 is found, and a second line segment B2 is obtained.

When all the second line segments have been searched (s24: yes), the processor obtains all intersections of the first line segment and the second line segment (s25), and outputs the intersections as pressure points (s26).

For example, the processor may obtain an intersection of the first line segment and the second line segment for all combinations of the first line segment and the second line segment.

In FIG. 11, the processor obtains an intersection c1 of the first line segment A1 and the second line segment B1 and an intersection c2 of the first line segment A2 and the second line segment B2 by obtaining an intersection of the first line segment and the second line segment for combinations (A1, B1), (A1, B2), (A2, B1), and (A2, B2) of the first line segment and the second line segment.

In the exemplary aspect, the processor repeats steps s21 to s26 every certain period (e.g., a predefined period). In this manner, the pressure sensor of the first modification detects the pressure point.

In the modification, the processor may be provided with a maximum number of pressure points in advance. Then, when the maximum number of the first line segments, the second line segments, or the intersections is found, the processor may end the search for the first line segment, the second line segment, or the intersection and proceed to the next processing.

In another modification, the processor may execute steps s21 and s22 after executing steps s23 and s24.

It is noted that, when the first line segment, the second line segment, or the intersection cannot be found, the processor determines that there is no pressure point and outputs nothing.

According to the first modification, the piezoelectric sensor has a simple structure including the piezoelectric film sensor and the supporting member as described above. The processor is configured to detect all the pressure points by obtaining all the intersections of the first line segment and the second line segment. Therefore, in the first modification, the pressing at not only one point but also a plurality of points can be detected by a simple structure.

### Second Modification

A pressure sensor of a second modification is different from the pressure sensor of the first modification in the following points. That is, the processor obtains a rectangular region which is defined by a rectangle having vertices defined by two intersections selected from among intersections of the first line segment and the second line segment and having a side parallel to the x-axis direction and in which the polarization takes a value of 0.

The pressure sensor of the second modification is configured to detect pressure at one point or a plurality of points.

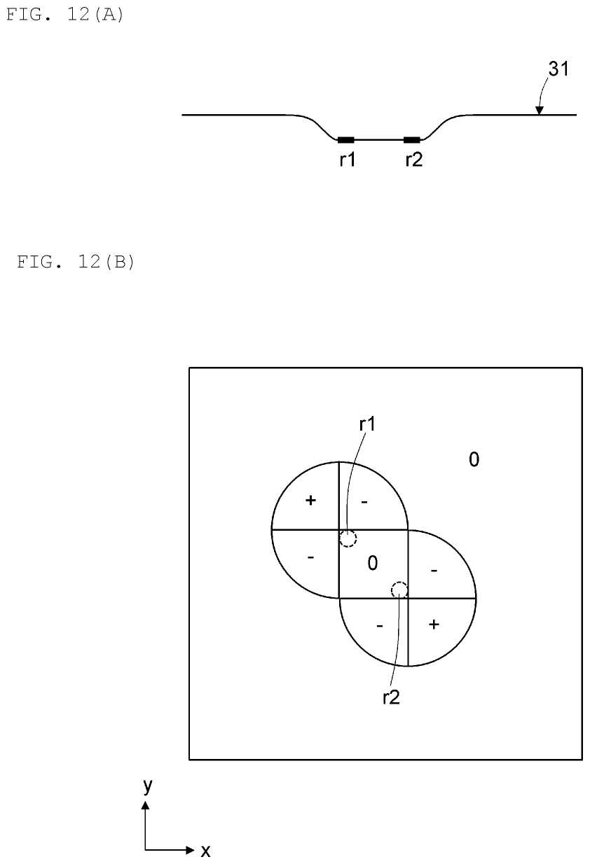

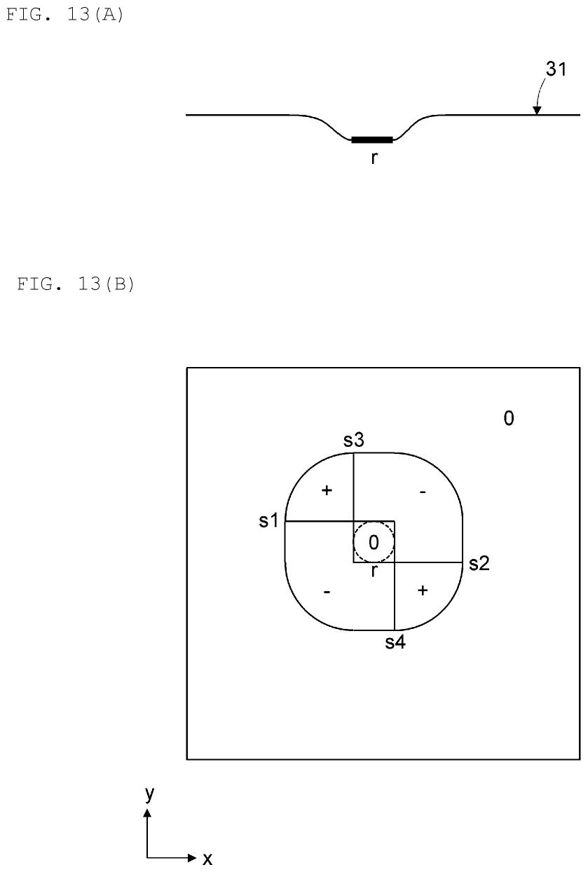

FIG. 12 (A) is a conceptual diagram illustrating an example of deformation of the principal surface 31 of the piezoelectric film sensor against pressure. FIG. 12 (B) is a conceptual diagram illustrating polarization of the piezoelectric film when the principal surface 31 of the piezoelectric film sensor is deformed as illustrated in FIG. 12 (A). FIG. 13 (A) is a conceptual diagram illustrating another example of deformation of the principal surface 31 of the piezoelectric film sensor against pressure. FIG. 13 (B) is a conceptual diagram illustrating an example of polarization of the piezoelectric film when the principal surface 31 of the piezoelectric film sensor is deformed as illustrated in FIG. 13 (A).

In FIG. 12 (A) to 13 (B), the pressing region is not regarded as a point having a minimum area and is explicitly drawn as a region having a certain area. The pressing region is a portion that comes into contact with the pressing body in the surface to be pressed when the pressing body presses the surface to be pressed. The pressing body is an object, such as a finger or the like, configured to perform a pressing operation.

FIG. 12 (A) illustrates a state when deformation of the principal surface 31 of the piezoelectric film sensor is viewed along a direction from a pressing region r1 toward a pressing region r2.

In FIG. 12 (A), the piezoelectric film sensor, that is, the piezoelectric film is locally deformed around the pressing regions r1 and r2. The deformation of the piezoelectric film in the pressing region r1 and the deformation of the piezoelectric film in the pressing region r2 are not separated but integrated. As illustrated in FIG. 12 (B), the polarization of the piezoelectric film locally changes around the pressing regions r1 and r2 and takes a value of 0 at a position away from the pressing regions r1 and r2. However, the polarization of the piezoelectric film takes a value of 0 in a rectangle having two sides in contact with the pressing region r1 and two sides in contact with the pressing region r2.

In FIG. 13 (A), the piezoelectric film sensor, that is, the piezoelectric film is locally deformed around the pressing region r. As illustrated in FIG. 13 (B), the polarization of the piezoelectric film locally changes around the pressing region r and takes a value of 0 at a position away from the pressing region r. However, the polarization of the piezoelectric film takes a value of 0 in a rectangle circumscribing the pressing region r.

In FIG. 13 (B), depending on the method of obtaining the first line segment and the second line segment and the dimension of the pressing region r, boundary lines s1 and s2 are detected as two separate first line segments or as a single first line segment having a relatively wide width, and the boundary lines s3 and s4 are detected as two separate second line segments or as a single second line segment having a relatively wide width.

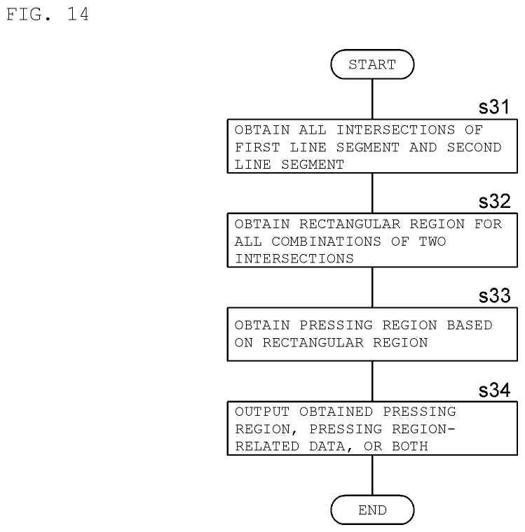

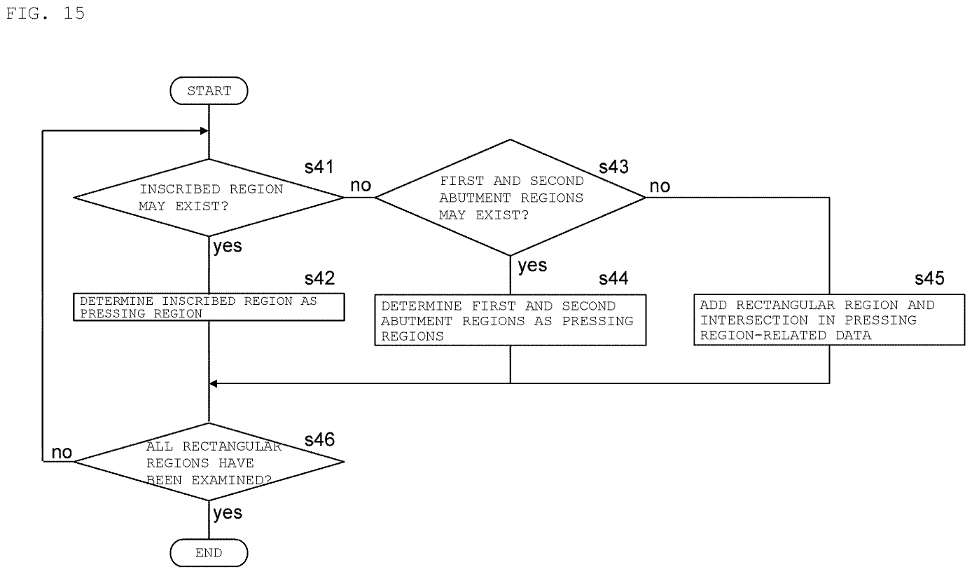

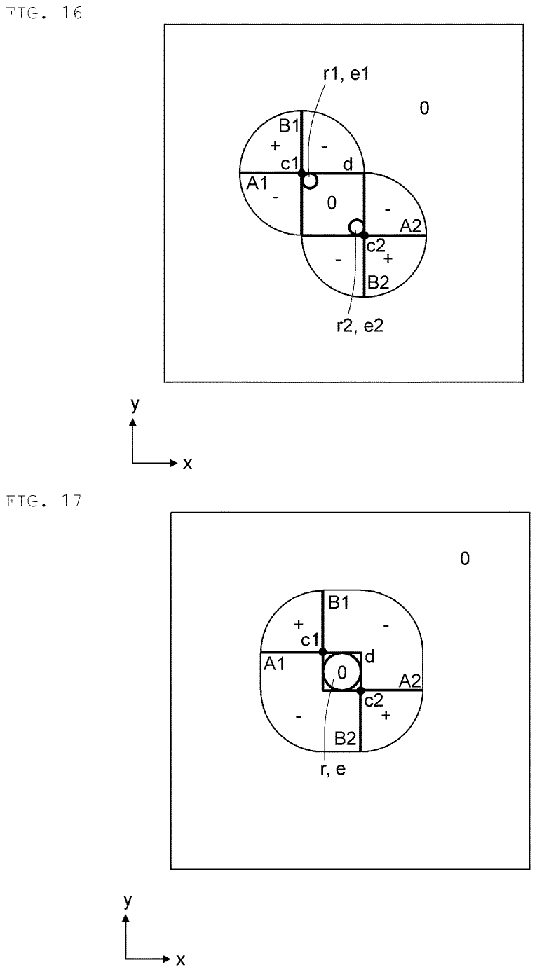

FIG. 14 is a flowchart illustrating pressure detection processing by the processor according to the second modification. FIG. 15 is a flowchart illustrating processing of step s33 by the processor according to the second modification. FIGS. 16 and 17 are conceptual diagrams for explaining pressure detection processing by the processor according to the second modification.

As illustrated in FIG. 14, the processor first executes processing similar to steps s21 to s26 illustrated in FIG. 10 to obtain all intersections of the first line segment and the second line segment (s31). Next, a rectangular region is obtained for all combinations of two intersections selected from the obtained intersections (s32). The rectangular region is defined by a rectangle having vertices defined by two selected intersections and having sides parallel to the x-axis direction and the y-axis direction, respectively, and has polarization with a value of 0.

In FIGS. 16 and 17, the processor obtains the intersection c1 between the first line segment A1 and the second line segment B1 and the intersection c2 between the first line segment A2 and the second line segment B2. Next, the processor obtains a rectangular region d for a combination of intersections (c1, c2).

Note that, in the present specification, the intersection between the first line segment and the second line segment does not include a point at which the distance from the end point of the first line segment or the second line segment is shorter than a predetermined threshold that defines the vicinity of the end point of the first line segment and the second line segment and is shared by the first line segment and the second line segment. Therefore, the processor determines that the point shared by the first line segment and the second line segment in the vicinity of the end point of the first line segment or the second line segment is not an intersection of the first line segment and the second line segment.

Next, the processor obtains the pressing region based on the rectangular region (s33).

Specifically, as illustrated in FIG. 15, when an inscribed region may exist (s41), the processor determines that the inscribed region is the pressing region (s42). The inscribed region has a surface shape of the pressing body and is defined as a region inscribed in the rectangular region. The surface shape of the pressing body is a shape of a portion of the surface of the pressing body that comes into contact with the surface receiving the pressure when the pressing body presses the surface receiving the pressure. Therefore, the surface shape of the pressing body matches the shape of the pressing region defined by the pressing body. The surface shape of the pressing body is provided to the processor in advance.

When the inscribed region cannot exist (s41: no) and the first and second abutment regions may exist (s43: yes), the processor determines the first and second abutment regions as pressing regions (s44). A first abutment region has a surface shape of the pressing body, is within a rectangular region, and is defined as a region in contact with two sides of the rectangular region sharing one intersection. A second abutment region is defined as a region that has a surface shape of the pressing body, does not overlap the first abutment region, is in a rectangular region, and is in contact with two sides of the rectangular region sharing the other intersection.

When a plurality of first or second abutment regions may exist, the processor may determine the first or second abutment region found first as the pressing region or may determine one first or second abutment region narrowed down by imposing an additional condition as the pressing region.

The processor can determine the presence of the inscribed region, the first abutment region, or the second abutment region by examining whether the region having the surface shape of the pressing body can be arranged so as to satisfy the definition of the inscribed region, the first abutment region, or the second abutment region.

In FIG. 16, the processor determines that the inscribed region cannot exist and the first and second abutment regions may exist and obtains a first abutment region e1 and a second abutment region e2. The first abutment region e1 has a surface shape of the pressing body, is in the rectangular region d, and is in contact with two sides of the rectangular region sharing the intersection c1. The second abutment region e2 has a surface shape of the pressing body, does not overlap the first abutment region e1, is in the rectangular region d, and is in contact with two sides of the rectangular region sharing the intersection c2.

In FIG. 17, the processor determines that an inscribed region may exist, and obtains an inscribed region e. The inscribed region e has a surface shape of the pressing body and is inscribed in the rectangular region d.

In an exemplary aspect, when the first and second abutment regions cannot exist (s43: no), the processor includes the rectangular region and the intersection at the vertex thereof in pressing region-related data. The pressing region-related data indicates that some pressing body is in contact within the rectangular region of the data and in the vicinity of the intersection of the data.

Moreover, when the processor has not finished searching for the pressing region and examining all the rectangular regions (s46: no), the processor continues searching for the pressing region and examining the remaining rectangular regions.

As illustrated in FIGS. 14 and 15, when the processor searches for the pressing region and examines all the rectangular regions (s46: yes), the processor outputs the obtained pressing region, pressing region-related data, or both (s34).

The processor repeats steps s31 to s34 every certain period. In this manner, the pressure sensor of the second modification detects the pressure point.

In the modification, when the surface shape of the pressing body is not provided in advance, the processor outputs the pressing region-related data including the obtained rectangular region and the intersection at the vertex.

In another modification, the processor may be provided with the surface shapes of the plurality of pressing bodies in advance. In this case, the processor may order the surface shapes of the plurality of pressing bodies. Then, when the inscribed region cannot exist in the surface shape of the previous pressing body, the processor may determine whether the inscribed region may exist in the surface shape of the next pressing body. Similarly, if the first and second abutment regions cannot exist with respect to the surface shape of the previous pressing body, the processor may determine whether the first and second abutment regions may exist with respect to the surface shape of the next pressing body.

In another modification, the processor may be provided with the maximum number of pressure points in advance. In this case, when the processor determines that the maximum number of pressure points can be obtained in the middle of the processing, the processor can then proceed to the next processing.

It is noted that, when the intersection cannot be found, the processor can be configured to determine that there is no pressure point and outputs nothing. Furthermore, when the found intersection is not at the vertex of the rectangular region, the processor is configured to output the intersection as the pressure point.

According to the second modification, pressure at a plurality of points can be detected even when deformation of the principal surface at the plurality of pressure points is not separated.

### Third Modification

According to an exemplary aspect, a pressure sensor of a third modification is different from the pressure sensor 1 in the following points. That is, the pressure sensor of the third modification includes a piezoelectric sensor 11a instead of the piezoelectric sensor 11.

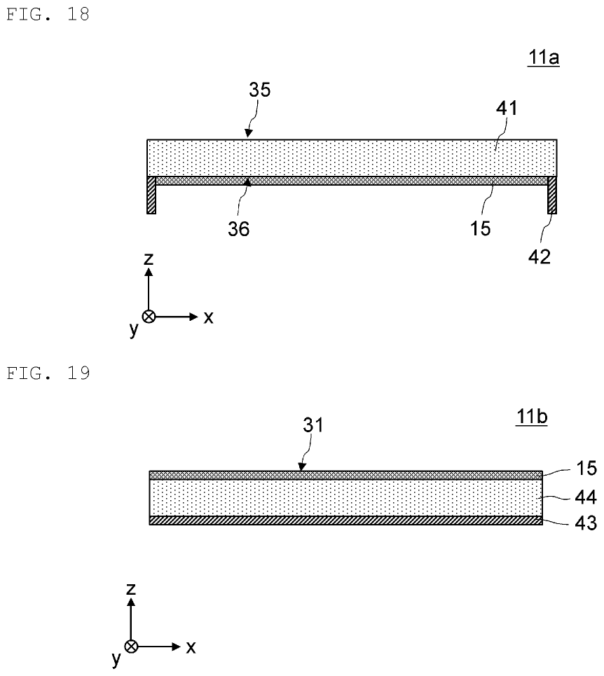

FIG. 18 is a sectional view of the piezoelectric sensor 11a. As shown, the piezoelectric sensor 11a includes the piezoelectric film sensor 15, a flat elastic body 41, and a fixture 42. The elastic body 41 has a first principal surface 35 and a second principal surface 36 opposite to the first principal surface 35. The fixture 42 fixes the elastic body 44 at an end of the second principal surface 36 of the elastic body 41. The piezoelectric film sensor 15 is arranged on the second principal surface 36 of the elastic body 41.

In this aspect, the pressure sensor of the third modification is configured to detect pressure at one point of the elastic body 41 against the first principal surface 35.

The elastic body 41 is formed of, for example, a glass plate. The fixture 42 is, for example, an exterior of a product on which a pressure sensor is mounted. The piezoelectric film sensor 15 is attached to the second principal surface 36 of the elastic body 41 with, for example, an adhesive or a pressure-sensitive adhesive.

The elastic body is fixed at an end of the second principal surface and is entirely bent by pressure without substantially changing the thickness thereof. The piezoelectric film sensor, that is, the piezoelectric film is arranged on the second principal surface of the elastic body. Therefore, when the first principal surface of the elastic body is pressed, deformation of the piezoelectric film propagates to the entire piezoelectric film, and polarization generated in the piezoelectric film extends to the entire piezoelectric film. Due to such characteristics, the pressure sensor of the third modification is suitable for detecting pressure at one point.

According to the present modification, the piezoelectric film sensor is arranged on the second principal surface of the elastic body. With such a structure, it is easy to industrially manufacture the pressure sensor, and mass productivity of the pressure sensor is secured.

### Fourth Modification

In an exemplary aspect, a pressure sensor of a fourth modification is different from the pressure sensor 1 in the following points. That is, the pressure sensor of the fourth modification includes a piezoelectric sensor 11b instead of the piezoelectric sensor 11.

FIG. 19 is a sectional view of the piezoelectric sensor 11b. As shown, the piezoelectric sensor 11b includes the piezoelectric film sensor 15, a hard bottom plate 43, and a flat elastic body 44. The elastic body 44 is arranged between the piezoelectric film sensor 15 and the bottom plate 43. The elastic body 44 is attached to the piezoelectric film sensor 15 and the bottom plate 43 by, for example, an adhesive or a pressure-sensitive adhesive. The elastic body 44 is formed of a material such as rubber or sponge and changes its thickness by pressure.

The pressure sensor of the fourth modification is configured to detect pressure applied to the principal surface 31 of the piezoelectric film sensor 15.

According to the present modification, the piezoelectric film sensor is arranged on the principal surface of the elastic body. With such a structure, it is easy to industrially manufacture the pressure sensor, and mass productivity of the pressure sensor is secured.

In addition, by using the pressure detection processing of the pressure sensor 1, the pressure sensor 1 in the first modification, or in the second modification, pressure can be detected at one point or a plurality of points.

In general, it is noted that the configurations described in each of the above embodiments may be appropriately replaced or combined.

Moreover, it is noted that description of the present embodiment is to be considered in all respects as illustrative and not limiting.

### DESCRIPTION OF REFERENCE SYMBOLS

1: Pressure sensor
11, 11a, 11b: Piezoelectric sensor
12: Detection unit
13: Processor
15: Piezoelectric film sensor
16: Supporting member
21: Piezoelectric film
22: Adhesive
23: Adhesive
24: Detection electrode
25: Ground electrode
26: Flexible substrate
27: Flexible substrate
31: Principal surface
33: First principal surface
34: Second principal surface
35: First principal surface
36: Second principal surface
41: Elastic body
42: Fixture
43: Bottom plate
44: Elastic body

What is claimed:

1. A pressure sensor comprising:
a piezoelectric film including a first principal surface and a second principal surface opposite to the first principal surface;
a plurality of detection electrodes on the first principal surface of the piezoelectric film and configured to detect charges generated in the piezoelectric film;
a ground electrode on the second principal surface of the piezoelectric film;
a detection unit configured to detect a voltage signal generated in the piezoelectric film from a charge detected by at least one of the plurality of detection electrodes; and
a processor configured to:
define a first direction and a second direction perpendicular to the first direction on the first principal surface of the piezoelectric film,
determine a distribution of polarization on the first principal surface of the piezoelectric film based on the detected voltage signal;
obtain a first line segment extending in the first direction that forms a boundary at which the polarization discontinuously changes among a positive value, a negative value, and a value of 0;
obtain a second line segment extending in the second direction that forms a boundary at which the polarization discontinuously changes among a positive value, a negative value, and a value of 0; and
detect a pressure point based on an intersection between the first line segment and the second line segment.

2. The pressure sensor according to claim 1, wherein the processor is configured to obtain a plurality of first line segments including the first line segment and a plurality of second line segments including the second line segment, and determine all intersections between the first line segments and the second line segments.

3. The pressure sensor according to claim 1, wherein the processor is configured to obtain a rectangular region defined by a rectangle having vertices defined by two intersections selected from among intersections of the first line segment and the second line segment and having a side parallel to the first direction and in which the polarization takes a value of 0.

4. The pressure sensor according to claim 1, further comprising:
an elastic body having a flat plate shape that includes a first principal surface and a second principal surface opposite to the first principal surface; and
a fixture that fixes the elastic body at an end of the second principal surface of the elastic body.

5. The pressure sensor according to claim 4, wherein the piezoelectric film is on the second principal surface of the elastic body.

6. The pressure sensor according to claim 1, further comprising:
a bottom plate; and
an elastic body having a flat plate shape,
wherein the elastic body is arranged between the piezoelectric film and the bottom plate.

7. The pressure sensor according to claim 1, wherein the piezoelectric film has output anisotropy.

8. A pressure point detection method in a pressure sensor that includes a piezoelectric film including a first principal surface and a second principal surface opposite to the first principal surface, a plurality of detection electrodes on the first principal surface of the piezoelectric film and configured to detect charges generated in the piezoelectric film, a ground electrode on the second principal surface of the piezoelectric film, a detection unit that detects a voltage signal generated in the piezoelectric film from a charge detected by the detection electrode, and a processor that processes the voltage signal detected by the detection unit, the method comprising:
defining, by the processor, a first direction and a second direction perpendicular to the first direction on the first principal surface of the piezoelectric film,
determining, by the processor, a distribution of polarization on the first principal surface of the piezoelectric film based on a voltage signal;
obtaining, by the processor, a first line segment extending in the first direction that forms a boundary at which the polarization discontinuously changes among a positive value, a negative value, and a value of 0;
obtaining, by the processor, a second line segment extending in the second direction that forms a boundary at which the polarization discontinuously changes among a positive value, a negative value, and a value of 0; and
detecting, by the processor, a pressure point by obtaining an intersection of the first line segment and the second line segment.

9. The pressure point detection method according to claim 8, further comprising:
obtaining, by the processor, a plurality of first line segments including the first line segment and a plurality of second line segments including the second line segment; and
determining, by the processor, all intersections between the first line segments and the second line segments.

10. The pressure point detection method according to claim 8, further comprising obtaining, by the processor, a rectangular region defined by a rectangle having vertices defined by two intersections selected from among intersections of the first line segment and the second line segment and having a side parallel to the first direction and in which the polarization takes a value of 0.

11. The pressure point detection method according to claim 8, wherein the pressure sensor further comprises:
an elastic body having a flat plate shape that includes a first principal surface and a second principal surface opposite to the first principal surface; and
a fixture that fixes the elastic body at an end of the second principal surface of the elastic body.

12. The pressure point detection method according to claim 8, further comprising arranging an elastic body having a flat plate shape between a bottom plate and the piezoelectric film.

13. The pressure point detection method according to claim 8, wherein the piezoelectric film has output anisotropy.

14. A non-transitory computer-readable storage medium having instructions stored thereon for a pressure point detection program for a pressure sensor that includes a piezoelectric film including a first principal surface and a second principal surface opposite to the first principal surface, a plurality of detection electrodes on the first principal surface of the piezoelectric film and configured to detect charges generated in the piezoelectric film, a ground electrode on the second principal surface of the piezoelectric film, a detection unit that detects a voltage signal generated in the piezoelectric film from a charge detected by the detection electrode, and a processor that processes the voltage signal detected by the detection unit, wherein the instructions for the pressure point detection program, when executed by the processor, cause the processor to perform operations comprising:
defining a first direction and a second direction perpendicular to the first direction on the first principal surface of the piezoelectric film;
determining a distribution of polarization on the first principal surface of the piezoelectric film based on a voltage signal;
obtaining a first line segment extending in the first direction that forms a boundary at which the polarization discontinuously changes among a positive value, a negative value, and a value of 0;
obtaining a second line segment extending in the second direction that forms a boundary at which the polarization discontinuously changes among a positive value, a negative value, and a value of 0; and
detecting a pressure point by obtaining an intersection of the first line segment and the second line segment.

15. The non-transitory computer-readable storage medium according to claim 14, wherein the instructions for the pressure point detection program, when executed by the processor, cause the processor to obtain a plurality of first line segments including the first line segment and a plurality of second line segments including the second line segment, and determine all intersections between the first line segments and the second line segments.

16. The non-transitory computer-readable storage medium according to claim 14, wherein the instructions for the pressure point detection program, when executed by the processor, cause the processor to obtain a rectangular region defined by a rectangle having vertices defined by two intersections selected from among intersections of the first line segment and the second line segment and having a side parallel to the first direction and in which the polarization takes a value of 0.

17. The non-transitory computer-readable storage medium according to claim 14, wherein the pressure sensor includes:
an elastic body having a flat plate shape that includes a first principal surface and a second principal surface opposite to the first principal surface; and
a fixture that fixes the elastic body at an end of the second principal surface of the elastic body.

18. The non-transitory computer-readable storage medium according to claim 14, wherein the piezoelectric film is on the second principal surface of the elastic body.

19. The non-transitory computer-readable storage medium according to claim 14, wherein the pressure sensor includes:
a bottom plate; and
an elastic body having a flat plate shape,
wherein the elastic body is arranged between the piezoelectric film and the bottom plate.

20. The non-transitory computer-readable storage medium according to claim 14, wherein the piezoelectric film has output anisotropy.
